(19) United States
(12) Patent Application Publication
(10) Pub. No.: US 2012/0282783 A1
(43) Pub. Date: Nov. 8, 2012

(54) METHOD FOR FABRICATING HIGH-K DIELECTRIC LAYER

(76) Inventors: Jui-Chen Chang, Kaohsiung City (TW); Chen-Kuo Chiang, Tainan City (TW); Chin-Fu Lin, Tainan City (TW); Chih-Chien Liu, Taipei City (TW)

(21) Appl. No.: 13/099,363

(22) Filed: May 3, 2011

(51) Int. Cl. H01L 21/469

(52) U.S. Cl. 438/763; 257/E21.487

(57) ABSTRACT

A method for fabricating high-k dielectric layer is disclosed. The method includes the steps of: providing a substrate; and forming a plurality of high-k dielectric layers by using a plurality of reacting gases to perform a plurality of process stages on the surface of the substrate, wherein at least one of the reacting gases comprises different flow rate in the fabrication stages.

### BACKGROUND OF THE INVENTION

1. Field of the Invention

The invention relates to a method for fabricating high-k dielectric layer, and more particularly, to a method for fabricating high-k dielectric layer with low gate leakage current.

2. Description of the Prior Art

With a trend towards scaling down size of the semiconductor device, conventional methods, which are used to achieve optimization, such as reducing thickness of the gate dielectric layer, for example the thickness of silicon dioxide layer, have faced problems such as leakage current due to tunneling effect. In order to keep progression to next generation, high-K materials are used to replace the conventional silicon oxide to be the gate dielectric layer because it decreases physical limit thickness effectively, reduces leakage current, and obtains equivalent capacitor in an identical equivalent oxide thickness (EOT).

On the other hand, the conventional polysilicon gate also has faced problems such as inferior performance due to boron penetration and unavoidable depletion effect which increases equivalent thickness of the gate dielectric layer, reduces gate capacitance, and worsens a driving force of the devices. Thus work function metals are developed to replace the conventional polysilicon gate to be the control electrode that competent to the high-K gate dielectric layer.

However, there is always a continuing need in the semiconductor processing art to develop semiconductor device renders superior performance and reliability even though the conventional silicon dioxide or silicon oxynitride gate dielectric layer is replaced by the high-K gate dielectric layer and the conventional polysilicon gate is replaced by the metal gate.

### SUMMARY OF THE INVENTION

It is an objective of the present invention to provide a method for fabricating high-k dielectric layer for lowering the gate leakage current in conventional high-k dielectric layer.

According to a preferred embodiment of the present invention, a method for fabricating high-k dielectric layer is disclosed. The method includes the steps of: providing a substrate; and using a plurality of reacting gases to perform a plurality of process stages for forming a plurality of high-k dielectric layers on the surface of the substrate, wherein at least one of the reacting gases comprises different flow rate in the fabrication stages.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a method for fabricating a high-k dielectric layer according to a preferred embodiment of the present invention.

FIG. 2 illustrates a perspective view of a reaction chamber according to a preferred embodiment of the present invention.

FIG. 3 is a table illustrating a relationship among the flow rate of the reacting gases in the plurality of process cycles, gate leakage current (Jg) and equivalent oxide thickness (EOT).

FIG. 4 is a relational diagram between Jg and EOT.

FIG. 5 is a structural view illustrating a high-k first approach according to an embodiment of the present invention.

FIG. 6 is a structural view illustrating a high-k last approach according to an embodiment of the present invention.

### DETAILED DESCRIPTION

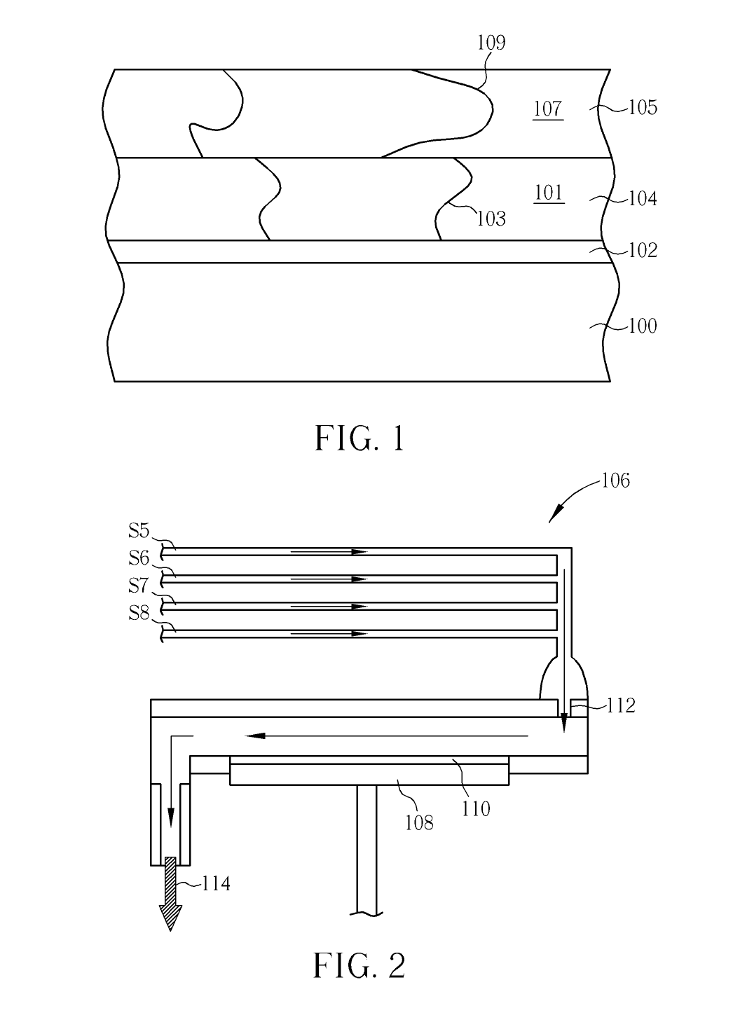

Referring to FIG. 1, FIG. 1 illustrates a method for fabricating a high-k dielectric layer according to a preferred embodiment of the present invention. As shown in FIG. 1, a substrate 100, such as a silicon wafer or a silicon-on-insulator (SOI) substrate is provided.

Next, an interfacial layer 102 composed of dielectric material such as oxides or nitrides is formed on the substrate 100, and an atomic layer deposition (ALD) process is performed to form a plurality of high-k dielectric layers 104, 105 having misaligned lattice structure on the interfacial layer 102. Despite only two layers of high-k dielectric layers 104, 105 are illustrated in this embodiment, the number of layers of the high-k dielectric layer could be adjusted according to the demand of the product.

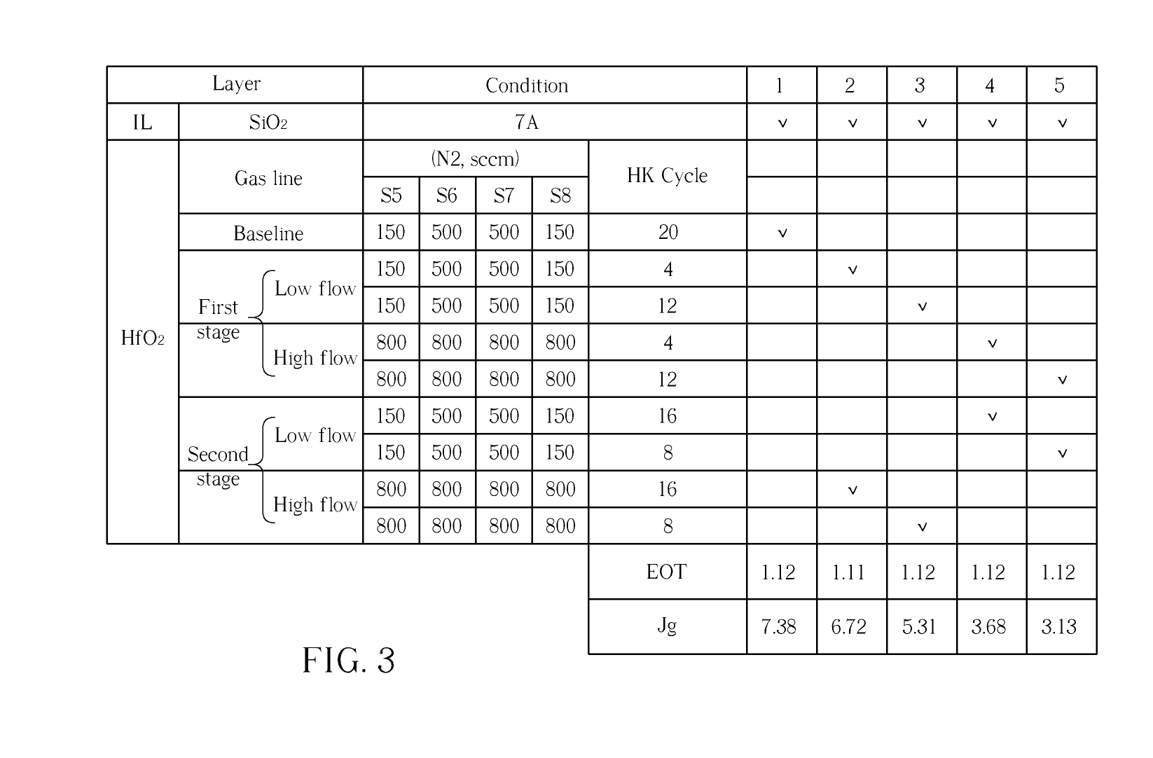

Preferably, the details of the ALD process is explained below. As shown in FIG. 2, a reaction chamber 106 is first provided, in which the chamber 106 includes a wafer stage 108, the substrate 100 from FIG. 1 disposed on the wafer stage 108, a gas inlet 112, and a vacuum pump 114. The gas inlet 112 of the reaction chamber 106 is connected to at least four pipe lines, such as the lines S5, S6, S7, and S8. In this embodiment, the carrier gas used is preferably nitrogen gas, but not limited thereto. The lines S5 and S8 are purge lines used for carrying a carrier gas under a vacuum environment to remove excess atoms. Lines S6 and S7 are pulse lines for carrying precursor and oxidant surface for forming the high-k dielectric layers 104, 105. Preferably, the oxidant source used for forming the high-k dielectric layer is water vapor and the precursor used is HfCl₄.

As the ALD process is conducted, water vapor is first brought into the reaction chamber 106 through line S7, and nitrogen gas is injected through line S8 to remove excess water vapor or water vapor that has not been attached onto the substrate 100. Next, precursor such as HfCl₄ is injected from line S6 to be mixed with the oxidant source for forming a high-k dielectric layer 104 composed of HfO₂ on the surface of the substrate 100. Nitrogen gas is then injected from line S5 to remove excess HfCl₄. Preferably, the temperature of the chamber is maintained at 300° C. while the pressure of the chamber is maintained at 3 Torr. It should be noted that as the oxidant source and precursor are carried by nitrogen into the pulse lines S6 and S7, the line S6 would carry both nitrogen gas and precursor simultaneously while the line S7 carries both nitrogen gas and oxidant source simultaneously. The purge lines S5 and S8 on the other hand contain only nitrogen gas.

By sequentially injecting reacting gases from the aforementioned lines S7, S8, S6, and S5 to form the high-k dielectric layer, a process cycle is completed. In this embodiment, after a high-k dielectric layer is formed on the surface of the substrate from one process cycle, multiple process cycles could be carried out repeatedly to form a plurality of high-k dielectric layers on the substrate. According to a preferred embodiment of the present invention, as a plurality of high-k dielectric layers are formed on the substrate surface through multiple process cycles, at least one of the oxidant source or precursor from the reacting gases used for conducting the process cycles preferably have different flow rate in the process cycles.

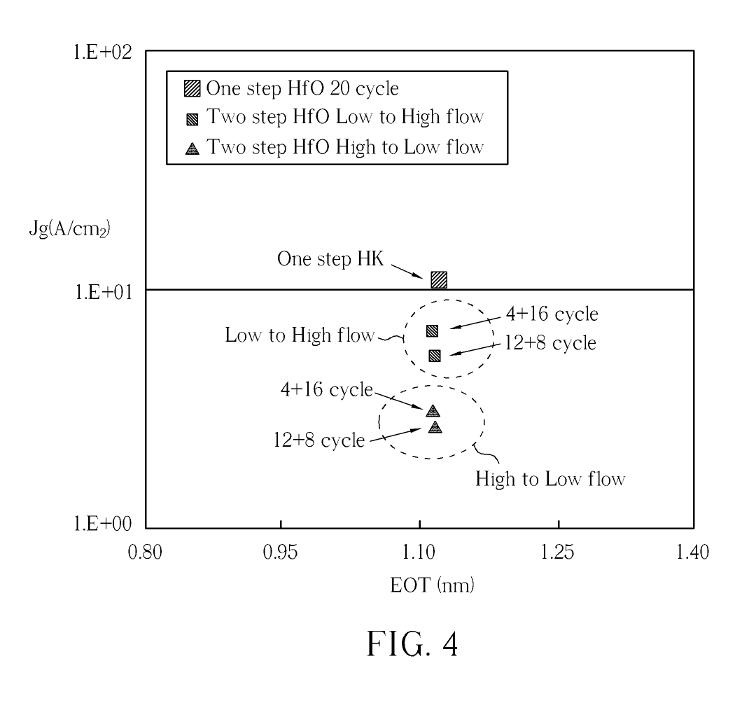

The variation of the flow rate of the reacting gases in the process cycles is explained below. Referring to FIGS. 3-4, FIG. 3 is a table illustrating a relationship among the flow rate of the reacting gases in the plurality of process cycles, the gate leakage current (Jg) and equivalent oxide thickness (EOT), FIG. 4 is a relational diagram between the Jg and EOT.

As shown in FIGS. 3-4, wafer 1 indicates a high-k dielectric layer fabricated from a single process cycle ALD process while wafers 2-5 indicate high-k dielectric layers fabricated from different gas flow of the present invention.

In this embodiment, the wafers 2-5 are all fabricated by injecting nitrogen gas, water vapor, and HfCl₄ from the lines S5, S6, S7, and S8 to perform a total of 20 process cycles. Taking wafer 2 as an example, a first process stage containing a total of 4 process cycles is first conducted, and a second process stage containing a total of 16 process cycles is performed to form a plurality of high-k dielectric layers on the substrate. Preferably, the flow rates of the reacting gases, including that of nitrogen gas, water vapor, and HfCl₄ in the first process stage are all less than the flow rates of the reacting gases in the second process stage, and the equivalent oxide thickness obtained from this fabrication recipe is 1.11 nm while the gate leakage current is 6.72 A/cm².

The fabrication recipe of wafer 3 involves performing a first process stage of a total of 12 process cycles, and a second process stage of a total of 8 process cycles, in which the flow rates of the reacting gases, including that of nitrogen gas, water vapor, and HfCl₄ in the first process stage are all less than the flow rates of the reacting gases in the second process stage. The equivalent oxide thickness obtained from this fabrication recipe is 1.12 nm while the gate leakage current is 5.31 A/cm².

The fabrication recipe of wafer 4 involves performing a first process stage of a total of 4 process cycles, and a second process stage of a total of 16 process cycles, in which the flow rates of the reacting gases, including that of nitrogen gas, water vapor, and HfCl₄ in the first process stage are all greater than the flow rates of the reacting gases in the second process stage. The equivalent oxide thickness obtained from this fabrication recipe is 1.12 nm while the gate leakage current is 3.68 A/cm².

The fabrication recipe of wafer 5 involves performing a first process stage of a total of 12 process cycles, and a second process stage of a total of 8 process cycles, in which the flow rates of the reacting gases, including that of nitrogen gas, water vapor, and HfCl₄ in the first process stage are all greater than the flow rates of the reacting gases in the second process stage. The equivalent oxide thickness obtained from this fabrication recipe is 1.12 nm while the gate leakage current is 3.13 A/cm².

Overall, the equivalent oxide thickness obtained from the fabrication result of the present invention is substantially equivalent to the one obtained from conventional approach. However, a much greater improvement has been observed on the gate leakage current, such as the one found on wafer 5. In other words, by first using higher flow rates of reacting gases under greater quantity of process cycles, such as greater than half the total of the process cycles, and then using lower flow rates of reacting gases under lower quantity of process cycles, such as less than half the total of the process cycles, a substantially lower value of gate leakage current is achieved.

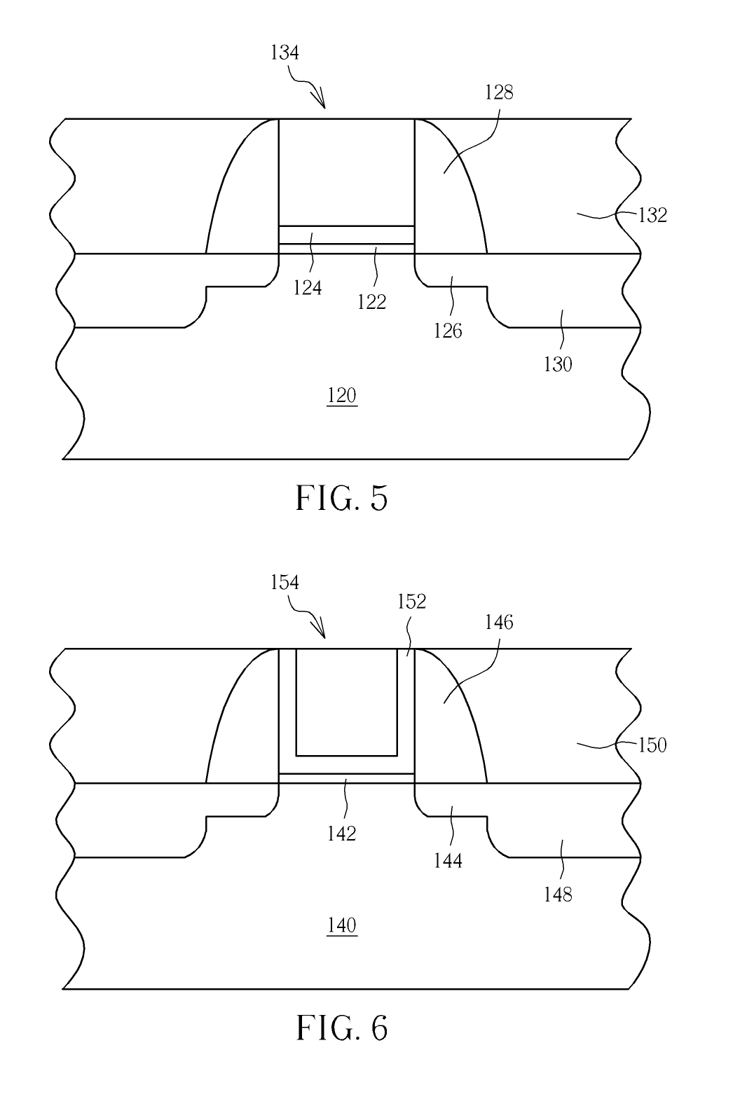

Moreover, the aforementioned approach for fabricating high-k dielectric layer could also be applied to a high-k first process or a high-k last process, which are all within the scope of the present invention. For instance, as shown in FIG. 5, a high-k first process could be accomplished by sequentially forming an interfacial layer 122 and a high-k dielectric layer 124 made from the process disclosed above on a substrate 120, forming a polysilicon layer (not shown) on the high-k dielectric layer 124, and conducting a pattern transfer process to form a dummy gate. After forming elements such as lightly doped drain 126, spacer 128, source/drain 130, and interlayer dielectric layer 132, the dummy gate is removed and metal and conductive materials are deposited to form a metal gate transistor 134. As the high-k dielectric layer 124 is formed before the dummy gate in this embodiment, the shape of the high-k dielectric layer 124 is preferably I-shaped.

In a high-k last approach, as shown in FIG. 6, an interfacial layer 142 could also be formed on a substrate 140, and a polysilicon layer (not shown) could be covered directly on the interfacial layer 142 and a pattern transfer is carried out to form a dummy gate. After forming elements such as lightly doped drain 144, spacer 146, source/drain 148, and interlayer dielectric layer 150, the dummy gate is removed and metal and conductive materials are deposited to form a metal gate transistor 154. As the high-k dielectric layer 152 is formed after the dummy gate is removed, the shape of the high-k dielectric layer 152 is preferably U-shaped.

Next, material layers such as barrier layer and polysilicon layer could be formed on the high-k dielectric layer, a dummy gate could be formed by patterning the barrier layer and the polysilicon layer, and lightly drains, spacer, source/drain region, and interlayer dielectric layers could be formed through standard metal gate transistor process. After removing the dummy gate to deposit required metal and conductive material, a metal gate transistor is completed. As these steps are well known to those skilled in the art, the details of which are omitted herein for the sake of brevity.

It should be noted the conventional approach for fabricating high-k dielectric layer typically forms a single layer of high-k dielectric layer on the substrate. However, a series of high temperature processes conducted afterwards, such as the anneal processes used for forming the lightly doped drain or source/drain regions often results in crystallization of the high-k dielectric layer. As grains of crystals are generated, electrical current could easily pass through the grain boundary between the grains of crystals and result in current leakage.

Referring back to FIG. 1, the first process stage having a plurality of process cycles is preferably conducted for forming the high-k dielectric layer 104 containing a plurality of grains 101 and a plurality of grain boundaries 103. The second process stage also having a plurality of process cycles is conducted to form the high-k dielectric layer 105 containing a plurality of grains 107 and a plurality of grain boundaries 109. By following this recipe, the present invention could use different process stage having different gas flow rates to change the grain status at each process stage, thereby forming a plurality of high-k dielectric layers having a misaligned grain structure, such as the high-k dielectric layers 104 and 105.

Overall, the present invention preferably performs an atomic layer deposition process to form a plurality of high-k dielectric layers on the surface of a substrate, in which the atomic layer deposition includes a plurality of process cycles and the process cycles include at least two types of process parameters, such as different flow rate of reacting gases. Viewing from another perspective, the present invention uses a plurality of reacting gases to perform a plurality of process stages for forming a plurality of high-k dielectric layers with misaligned lattice structure. According to the aforementioned embodiment, the flow rate of reacting gases is altered in different process stage, such as injecting a high flow of reacting gases in the first process stage and injecting a low flow of reacting gases in the second process stage. Each process stage could also be carried out by using reacting gases with high flow rate or low flow rate to perform greater quantity of process cycles, such as greater than half the total of process cycles, or could be carried by using reacting gases with high flow rate or low flow rate to perform fewer quantity of process cycles, such as less than half the total of process cycles. By changing the flow rates of the reacting gases in the process cycles, the present invention could form high-k dielectric layers on the substrate with substantially improved gate leakage current.

Those skilled in the art will readily observe that numerous modifications and alterations of the device and method may be made while retaining the teachings of the invention.

What is claimed is:

1. A method for fabricating high-k dielectric layer, comprising:
providing a substrate; and
forming a plurality of high-k dielectric layers on the surface of the substrate by using a plurality of reacting gases to perform a plurality of process stages, wherein at least one of the reacting gases comprises different flow rate in the fabrication stages.

2. The method of claim 1, wherein the process stages comprises a plurality of process cycles.

3. The method of claim 2, wherein the process cycles constitute an atomic layer deposition process.

4. The method of claim 1, further comprising forming an interfacial layer on the substrate before forming the high-k dielectric layer.

5. The method of claim 4, wherein the interfacial layer comprises silicon oxide.

6. The method of claim 1, wherein the reacting gases comprise nitrogen, water, and HfCl₄.

7. The method of claim 6, wherein the high-k dielectric layer comprises HfO₂.

8. The method of claim 2, wherein the step of performing the plurality of process cycles comprises:
(a) using the reacting gases to perform greater than half of the total of the process cycles;
(b) using the reacting gases to perform less than half of the total of the process cycles;
wherein the flow rate of the reacting gases in step (a) is less than the flow rate of the reacting gases in step (b).

9. The method of claim 2, wherein the step of performing the plurality of process cycles comprises:
(a) using the reacting gases to perform less than half of the total of the process cycles;
(b) using the reacting gases to perform greater than half of the total of the process cycles;
wherein the flow rate of the reacting gases in step (a) is less than the flow rate of the reacting gases in step (b).

10. The method of claim 2, wherein the step of performing the plurality of process cycles comprises:
(a) using the reacting gases to perform greater than half of the total of the process cycles;
(b) using the reacting gases to perform less than half of the total of the process cycles;
wherein the flow rate of the reacting gases in step (a) is greater than the flow rate of the reacting gases in step (b).

11. The method of claim 2, wherein the step of performing the plurality of process cycles comprises:
(a) using the reacting gases to perform less than half of the total of the process cycles;
(b) using the reacting gases to perform greater than half of the total of the process cycles;
wherein the flow rate of the reacting gases in step (a) is less than the flow rate of the reacting gases in step (b).

12. A method for fabricating high-k dielectric layer, comprising:
providing a substrate; and
performing an atomic layer deposition process for forming a plurality of high-k dielectric layers on the surface of the substrate, wherein the atomic layer deposition process comprises a plurality of process cycles and the process cycles comprise at least two type of process parameters.

13. The method of claim 12, further comprising using a plurality of reacting gases for performing the atomic layer deposition process, wherein the process parameters comprise different flow rate of the reacting gases.

14. The method of claim 12, further comprising forming an interfacial layer on the substrate before forming the high-k dielectric layer, wherein the interfacial layer comprises silicon oxide.

15. The method of claim 13, wherein the reacting gases comprise nitrogen, water, and HfCl₄.

16. The method of claim 12, wherein the high-k dielectric layer comprises HfO₂.

17. The method of claim 13, wherein the step of performing the plurality of process cycles comprises:
(a) using the reacting gases to perform greater than half of the total of the process cycles;
(b) using the reacting gases to perform less than half of the total of the process cycles;
wherein the flow rate of the reacting gases in step (a) is less than the flow rate of the reacting gases in step (b).

18. The method of claim 13, wherein the step of performing the plurality of process cycles comprises:
(a) using the reacting gases to perform less than half of the total of the process cycles;
(b) using the reacting gases to perform greater than half of the total of the process cycles;
wherein the flow rate of the reacting gases in step (a) is less than the flow rate of the reacting gases in step (b).

19. The method of claim 13, wherein the step of performing the plurality of process cycles comprises:
(a) using the reacting gases to perform greater than half of the total of the process cycles;
(b) using the reacting gases to perform less than half of the total of the process cycles;
wherein the flow rate of the reacting gases in step (a) is greater than the flow rate of the reacting gases in step (b).

20. The method of claim 13, wherein the step of performing the plurality of process cycles comprises:
(a) using the reacting gases to perform less than half of the total of the process cycles;
(b) using the reacting gases to perform greater than half of the total of the process cycles;
wherein the flow rate of the reacting gases in step (a) is less than the flow rate of the reacting gases in step (b).
